(19) United States
(12) Patent Application Publication
(10) Pub. No.: US 2023/0240002 A1
(43) Pub. Date: Jul. 27, 2023

(54) Capillary structure of cooling element, cooling element and preparation method thereof

(71) Applicant: AAC Technologies (Nanjing) Co., Ltd., Nanjing (CN)

(72) Inventors: Guochuang Huang, Shenzhen (CN); Hezhi Wang, Shenzhen (CN); Bo Zhang, Shenzhen (CN)

(21) Appl. No.: 17/833,737

(22) Filed: Jun. 6, 2022

(30) Foreign Application Priority Data
Jan. 27, 2022 (CN) 202210099847.4

(51) Int. Cl. H05K 1/02; H05K 3/22

(52) U.S. Cl. CPC H05K 1/0272; H05K 3/227

(57) ABSTRACT

The invention relates to the technical field of heat dissipation, and specifically provides a capillary structure element of a cooling element, wherein the capillary structure is formed by copper metal paste. The copper metal paste includes copper powder, binder, solvent, pore former, dispersant, stabilizer, surfactant, and antioxidant. The present invention also provides a cooling element comprising the capillary structure element and a preparation method thereof. The capillary structure element provided by the invention is arranged with the advantages of simple preparation process, convenient operation, controllable thickness, controllable size and hole diameter, excellent capillary effect and the like, and is especially suitable for preparing ultra-thin cooling elements.

### FIELD OF THE PRESENT DISCLOSURE

The invention belongs to the technical field of heat dissipation, and in particular relates to a capillary structure of a cooling element, a cooling element and a preparation method thereof.

### DESCRIPTION OF RELATED ART

The high-frequency and high-speed development of electronic components and integrated circuit technology has caused electronic components to generate a large amount of heat during operation.

For example, the heat flux density during the operation of computer CPU has reached 60-100 W/cm2, and even as high as 103 W/cm2 in semiconductor lasers. The reliability of electronic equipment is extremely sensitive to temperature, and the reliability will drop by 5% for every 1° C. increase in device temperature at the 70-80° C. level. High heat flow poses a great threat to the reliability of the normal operation of components, so heat dissipation has become a key issue in the development of miniaturization of electronic product. In order to ensure the normal operation of electronic components, a cooling element is usually installed on the electronic components to dissipate heat, which distributes the heat of the heating electronic components evenly, and then dissipates them through the radiator.

The cooling element includes a metal housing, a cooling medium encapsulated in the metal housing, and a capillary structure element that adsorbs the cooling medium, which realizes rapid heat transfer by means of the phase transition of the cooling medium. Wherein, the capillary structure of the cooling element directly affects the performance of the cooling element, and the capillary structure requires strong capillary force and low water flow resistance. There are many kinds of absorbent cores with capillary structure in the cooling element in the prior art, such as foamed copper, copper mesh, composite copper mesh, and etched capillary structure. However, the production cost of these capillary structures is relatively high, the production process is relatively complicated, and the market price is also relatively high. Such as foamed copper or composite copper mesh, etc., and because the capillary structure elements such as foamed copper, copper mesh/composite copper mesh, etc. themselves have a large thickness, it is impossible to make the cooling element develop in a thinner way.

Due to the continuous development of miniaturization of electronic product, other components are required to be smaller and thinner in size. This makes the cooling element put forward more stringent requirements on the thickness, such as ultra-thin cooling elements with a thickness of 280 μm or less (e.g. 240 μm) came into being. Ultra-thin cooling elements require thinner thicknesses while ensuring heat transfer performance. For example, capillary structure elements with a thickness of 80 μm or even 50 μm are on the agenda.

The capillary structure of the cooling element and the cooling element provided by the present invention, the copper metal paste is loaded in the upper cover by the blade coating method or the screen-printing method, and after drying and high-temperature sintering, capillary structure elements spread all over the through holes are obtained. The hole diameter of the capillary structure element is small, and the distribution is relatively uniform. Not only can it adapt to the size of the ultra-thin cooling element, but also easy to operate. It also is arranged with a strong capillary effect, so that it is arranged with excellent adsorption capacity, and can reduce the production cost to a greater extent.

### SUMMARY OF THE PRESENT INVENTION

The purpose of the present invention is to prepare a capillary structure element and a cooling element with excellent adsorption performance and adjustable thickness to be suitable for ultra-thin cooling elements.

Accordingly, the present invention provides a capillary structure element of a cooling element prepared and formed by copper metal paste; wherein the copper metal paste includes copper powder, binder, solvent, pore former, dispersant, stabilizer, surfactant, and antioxidant.

In addition, the capillary structure element is a three-dimensional interconnected hole structure with a hole diameter of 10-100 μm and a porosity of 30-80%.

In addition, the microscopic shape of the copper powder is spherical, and the particle size of the copper powder is 0.1-100 μm.

In addition, the binder is in PVA, epoxy resin, acrylic resin, phenolic resin, modified phenolic resin, hydroxymethyl cellulose and ethyl cellulose one or more; the solvent is one or more of ethanol, propanol, isopropanol, acetone, toluene, xylene, terpineol, triethanolamine, isophorone, divalent ester and water; the pore former is one or more of ammonium chloride, urea, ammonium sulfate, citric acid and benzoic acid; the dispersant is one or more of methyl amyl alcohol, cellulose derivatives, polyacrylamide and fatty acid polyethylene glycol ester; the stabilizer is one or more of phosphites, epoxy compounds and polyols; escribed surfactant is sodium dodecyl sulfate, sodium dodecyl benzene sulfonate, sodium tetradecyl sulfonate, sodium hexadecyl sulfonate, lecithin, triethanolamine, KH550, polyethylene glycol and triglyceride. One or more of ethanolamines; the antioxidant is one or more of citric acid, phytic acid, vitamin, oxalic acid, ascorbic acid and glucose.

In addition, a weight ratio of described copper powder and described pore former is 3:1˜1:1.

In addition, a weight fraction ratio of the mixture of the copper powder and the pore former to the copper metal paste is 50% to 80%.

The present invention further provides a cooling element comprising a lower cover, an upper cover that is covered and connected to the lower cover and forms an accommodation cavity with the lower cover, a cooling medium that is accommodated in the accommodation cavity, and a capillary structure element as described in claim 1 loaded on the upper cove, wherein the capillary structure element is accommodated in the accommodation cavity and adsorbs the cooling medium.

The present invention further provides a preparation method of a cooling element, comprising steps of:

providing an upper cover and a copper metal paste, wherein the copper metal paste is supported on the upper cover by a blade coating method or a screen-printing method; the copper metal paste on the upper cover is successively subjected to drying treatment and high temperature sintering treatment to obtain the capillary structure element as described in claim 1.

In addition, the drying process includes placing the upper cover loaded with the copper metal paste into an oven or a vacuum oven for drying process.

In addition, the high temperature sintering treatment is carried out in an atmosphere in which nitrogen is used as a protective gas and hydrogen is used as a reducing gas.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is an isometric view of a cooling element provided by the present invention;

FIG. 2 is a cross-sectional view of the cooling element shown in FIG. 1 taken along line AA;

FIG. 3 is an exploded structural diagram of the cooling element shown in FIG. 1;

FIG. 4 is a schematic diagram of a preparation method of the cooling element provided by the present invention;

FIG. 5 is a scanning electron microscope view of the capillary structure element of the cooling element provided by the present invention;

### DETAILED DESCRIPTION OF THE EXEMPLARY EMBODIMENTS

The present disclosure will hereinafter be described in detail with reference to exemplary embodiments. To make the technical problems to be solved, technical solutions and beneficial effects of the present disclosure more apparent, the present disclosure is described in further detail together with the figures and the embodiments. It should be understood the specific embodiments described hereby are only to explain the disclosure, not intended to limit the disclosure.

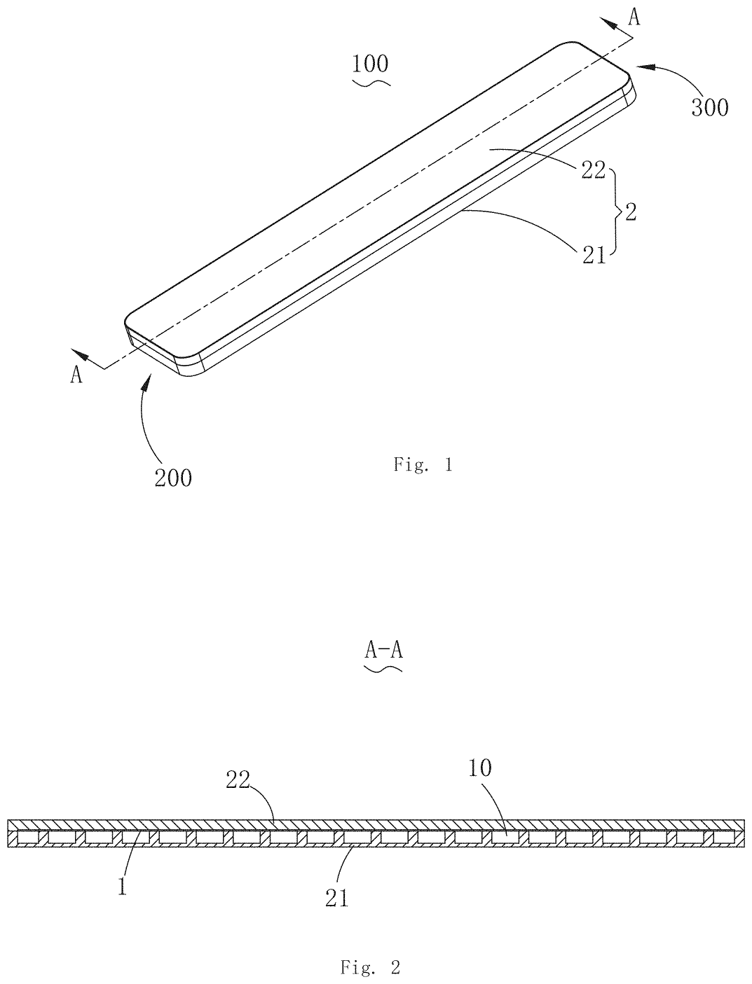

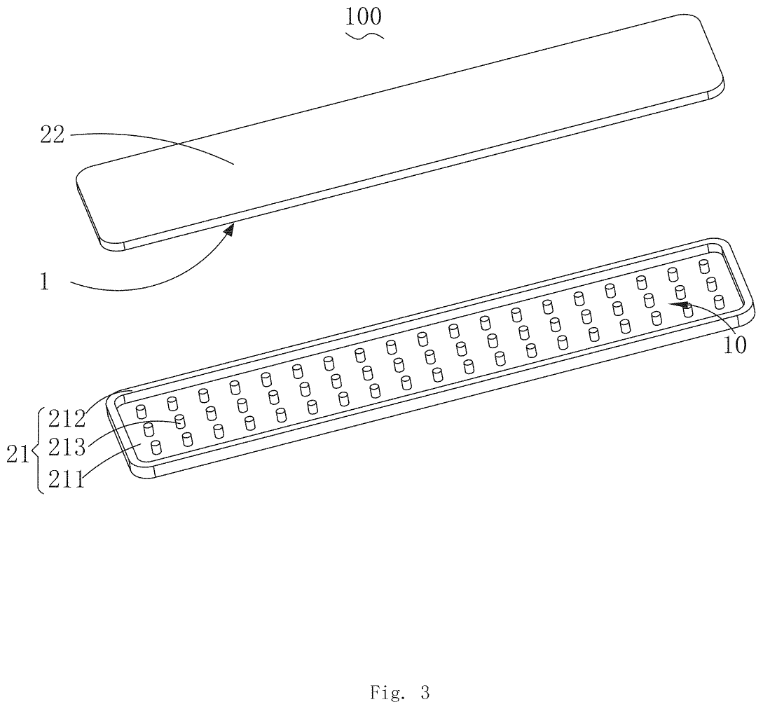

Please refer to FIG. 1 to FIG. 3, the embodiment of the present invention provides a capillary structure element 1 and a cooling element 100 including the capillary structure element 1.

Specifically, the cooling element 100 includes a metal housing 2, a capillary structure element 1, and a cooling medium. Wherein, the metal housing 2 is arranged with an accommodation cavity 10. And the metal housing 2 includes a lower cover 21 and an upper cover 22. The lower cover 21 includes a bottom wall 211, a side wall 212 and a protruding column 213. The side wall 212 extends from the edge of the bottom wall 211 toward the upper cover 22 and is in contact with the upper cover 22. The protruding column 213 extends from the bottom wall 211 toward the upper cover 22. At the same time, the protruding columns 213 are spaced apart. If the array can be distributed at intervals, the lower cover 21 and the upper cover 22 enclose and form an accommodation cavity 10. The capillary structure element 1 is the capillary structure element 1 obtained according to the preparation method provided by the present invention. Part/full of the capillary structure element 1 is embedded in the groove (not shown in the FIG.) of the upper cover 22. The capillary structure element 1 is accommodated in the accommodation cavity 10, which is away from the side of the upper cover 22 and abuts against the end of the protruding column 213. The cooling medium can be deionized water, ethanol, acetone, etc. The cooling medium is filled in the accommodation cavity 10 and adsorbed to the capillary structure element 1.

The cooling element 100 includes a hot end 200 attached to the heat source element and a cold end 100 disposed away from the hot end 200. The cooling element achieves the purpose of heat conduction through the phase transition of the cooling medium in the cooling element.

In order to better illustrate the technical solutions of the present invention, further explanations are given below through several embodiments.

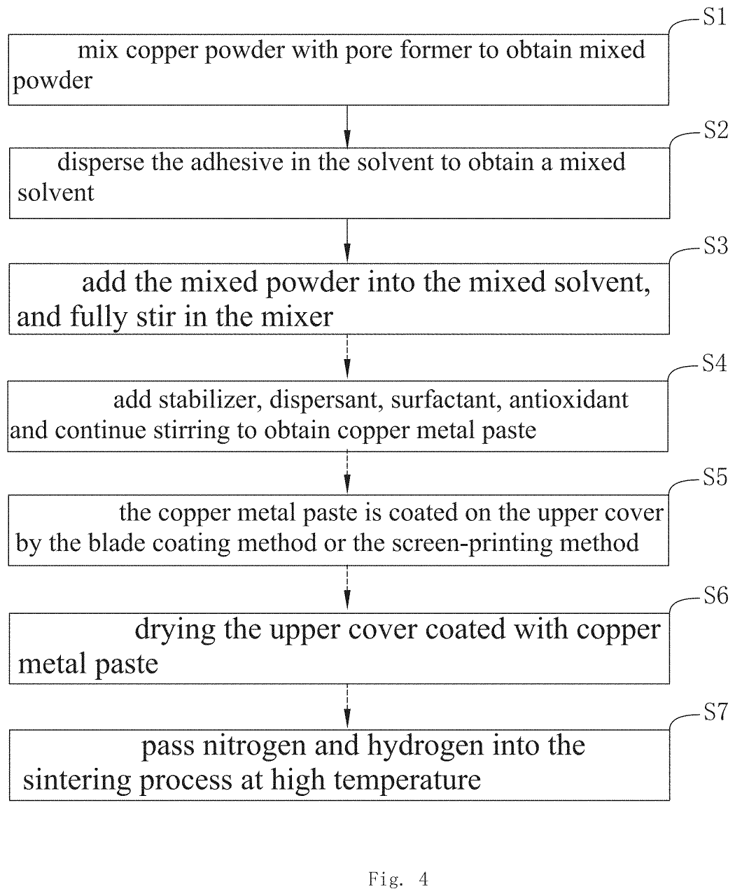

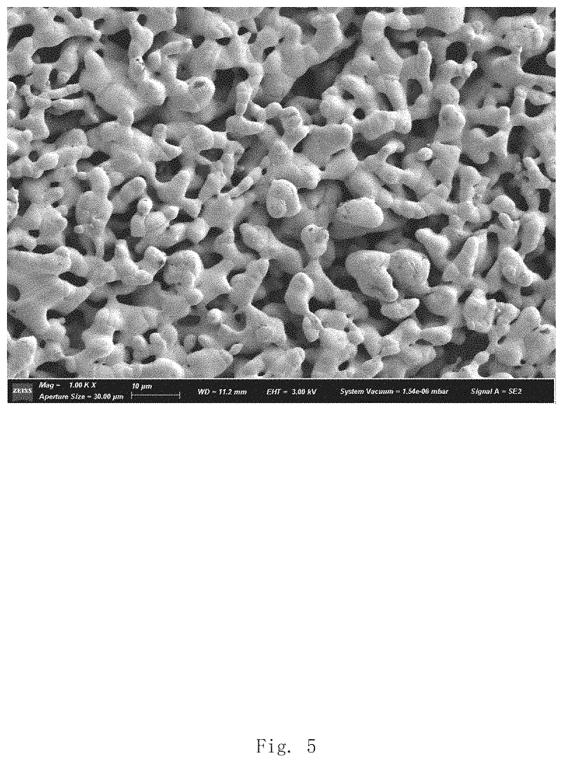

As shown in FIG. 4, it is a schematic view of the preparation method of the cooling element provided by the present invention, which includes: S1: mix copper powder with pore former to obtain mixed powder;

S2: disperse the adhesive in the solvent to obtain a mixed solvent;

S3: add the mixed powder into the mixed solvent, and fully stir in the mixer;

S4: add stabilizer, dispersant, surfactant, antioxidant and continue stirring to obtain copper metal paste;

S5: the copper metal paste is coated on the upper cover by the blade coating method or the screen-printing method;

S6: drying the upper cover coated with copper metal paste;

S7: pass nitrogen and hydrogen into the sintering process at high temperature.

More specifically, see embodiment 1-9 below:

Embodiment 1: Take the electrolytic copper powder with an average particle size of 10 μm, and ammonium chloride particles with a particle size of 70˜100 μm obtained by ball milling or crushing and sieving,

then mix together according to the weight ratio of 3:1 to obtain the mixed powder. The mixed powder accounts for 70% of the copper metal paste weight, and acrylic resin (PMMA) is dispersed in the solvent xylene as a binder to obtain a PMMA-xylene solution with a weight fraction of 25%. And add the mixed powder to 25% PMMA-xylene solution, after the mixer is fully stirred, add it in turn: Phosphite whose weight fraction accounts for 0.5% of copper metal paste as stabilizer, Methyl amyl alcohol whose weight fraction accounts for 0.5% of copper metal paste as dispersant,

Sodium dodecyl sulfate whose weight fraction accounts for 0.5% of copper metal paste as surfactant, the weight fraction of copper metal paste is 1% citric acid as antioxidant, and continue to stir for 0.5˜6 h. Scrape the mixed copper metal paste onto the upper cover of a specific cooling element, and then put it into an oven at 90˜110° C. for 20˜120 min. After drying the solvent, put it into the sintering furnace, pass N2/H2, and sinter at 700˜850° C. for 20˜120 min, and finally obtain the upper cover loaded with the capillary structure element. The upper cover and the lower cover are pasted with solder paste, and finally the finished cooling element is obtained, and the temperature difference between the cold end and the hot end is tested. At the same time, SEM and section tests were performed on it.

As shown in FIG. 5, the scanning electron microscope image of the capillary structure element of the cooling element provided by the present invention, the capillary structure element is a three-dimensional interconnected hole structure, its hole diameter is 10˜100 μm, porosity is 30˜80%, it has the characteristics of controllable hole structure and size, and has good surface weight and color.

In the copper metal paste provided by the present invention, the binder is used to bond the powder particles of copper powder and pore former, so that the powder will not fall off after drying, and these particles are firmly adhered to the upper cover of the cooling element. The solvent is used to dissolve the adhesive and disperse the copper powder and pore former. The pore former is arranged with the property of decomposing or volatilizing at high temperature, and can be used to form pores in the capillary structure. Dispersant can make copper powder and pore former powder more favorable for dispersion; stabilizer can be used to stabilize the suspension state of copper paste; surfactant can be used to reduce the surface tension of paste, which is beneficial to the stable existence of particles in copper paste. Antioxidant can effectively prevent copper powder from being oxidized by oxygen and water in the air, which is beneficial to prolong the settling time of copper paste.

In this embodiment, specific compounds are used as binder, solvent, pore former, dispersant, stabilizer, surfactant, and antioxidant in copper metal paste. However, those skilled in the art can understand that any compound that can meet the functional requirements of the above components can be used in copper metal paste.

Embodiment 2: Take the electrolytic copper powder with an average particle size of 1 μm, and ammonium chloride particles with a particle size of 70˜100 μm obtained by ball milling or crushing and sieving, then mix together according to the weight ratio of 3:1 to obtain the mixed powder. The mixed powder accounts for 70% of weight of the copper metal paste, this mixed powder is added in 25% PMMA-xylene solution. After the mixer is fully stirred, add 0.5% stabilizer, 0.5% dispersant, 0.5% surfactant, 1% antioxidant in sequence, and continue to stir for 0.5˜6 h. Paint the mixed copper metal paste into the upper cover of the specific cooling element. Then put it into an oven at 90˜110° C. for 20˜120 min. After drying the solvent, put it into a sintering furnace, pass in N2/H2, and sinter at 700˜850° C. for 20˜120 min. and finally obtain the upper cover with capillary structure element. The upper cover and the lower cover are pasted with solder paste, and finally the finished cooling element is obtained, and the temperature difference between the cold end and the hot end is tested.

Embodiment 3: Take the electrolytic copper powder with an average particle size of 10 μm, and ammonium chloride particles with a particle size of 70˜100 μm obtained by ball milling or crushing and sieving,

mix together according to the weight ratio of 2:1 to obtain the mixed powder, the mixed powder accounts for 50% of the weight of copper metal paste, the mixed powder is added to a 25% PMMA-xylene solution. After the mixer is fully stirred, add 0.5% stabilizer, 0.5% dispersant, 1% surfactant, and 1% antioxidant in sequence, and continue to stir for 0.5˜6 h. Paint the mixed metal paste into the upper cover of the specific cooling element, then put it into an oven at 90˜110° C. for 20˜120 min, after drying the solvent, put it into the sintering furnace, pass N2/H2, and sinter at 700˜850° C. for 20˜120 min, finally, the upper cover with capillary structure element is obtained. The upper cover and the lower cover are pasted with solder paste, and finally the finished cooling element is obtained, and the temperature difference between the cold end and the hot end is tested.

Embodiment 4: Take the electrolytic copper powder with an average particle size of 1 μm and ammonium chloride particles with a particle size of 70˜100 μm obtained by ball milling or crushing and sieving, then mix together according to the weight ratio of 2:1 to obtain the mixed powder, the mixed powder accounts for 90% of the weight of the copper metal paste. This mixed powder is added in 25% PMMA-xylene solution, after the mixer is fully stirred, add 0.5% stabilizer, 0.5% dispersant, 0.5% surfactant, 1% antioxidant in sequence, and continue to stir for 0.5˜6 h. Paint the mixed metal paste into the upper cover of the specific cooling element, then put it into an oven at 90˜110° C. for 20˜120 min, after drying the solvent, put it into the sintering furnace, pass N2/H2, and sinter at 700˜850° C. for 20˜120 min, finally, the upper cover with capillary structure element is obtained. The upper cover and the lower cover are pasted with solder paste, and finally the finished cooling element is obtained, and the temperature difference between the cold end and the hot end is tested.

Embodiment 5: Take the electrolytic copper powder with an average particle size of 10 μm and the ammonium chloride particles with a particle size of 70˜100 μm obtained by ball milling or crushing and sieving,

then mix together according to the weight ratio of 1:1 to obtain the mixed powder, the mixed powder accounts for 60% of the weight of the copper metal paste. This mixed powder is added in 25% PMMA-xylene solution, after the mixer is fully stirred, add 0.5% stabilizer, 0.5% dispersant, 1% surfactant, 1% antioxidant in sequence, and continue to stir for 0.5˜6 h. Paint the mixed metal paste into the upper cover of the specific cooling element, then put it into an oven at 90˜110° C. for 20˜120 min, after drying the solvent, put it into the sintering furnace, pass N2/H2, and sinter at 700˜850° C. for 20˜120 min, finally, the upper cover with capillary structure element is obtained. The upper cover and the lower cover are pasted with solder paste, and finally the finished cooling element is obtained, and the temperature difference between the cold end and the hot end is tested.

Embodiment 6: Take the electrolytic copper powder with an average particle size of 1 μm and ammonium chloride particles with a particle size of 70˜100 μm obtained by ball milling or crushing and sieving, then mix together according to the weight ratio of 1:1 to obtain the mixed powder. The mixed powder accounts for 70% of the weight of the copper metal paste. This mixed powder is added in 25% PMMA-xylene solution, after the mixer is fully stirred, add 0.5% stabilizer, 0.5% dispersant, 1% surfactant, 1% antioxidant in sequence, and continue to stir for 0.5˜6 h. Paint the mixed metal paste into the upper cover of the specific cooling element, then put it into an oven at 90˜110° C. for 20˜120 min, after drying the solvent, put it into the sintering furnace, pass N2/H2, and sinter at 700˜850° C. for 20˜120 min, finally, the upper cover with capillary structure element is obtained. The upper cover and the lower cover are pasted with solder paste, and finally the finished cooling element is obtained, and the temperature difference between the cold end and the hot end is tested.

Embodiment 7: Take the electrolytic copper powder with an average particle size of 1 μm, and ammonium chloride particles with a particle size of 70˜100 μm obtained by ball milling or crushing and sieving, then mix together according to the weight ratio of 3:1 to obtain the mixed powder. The mixed powder accounts for 60% of the weight of the copper metal paste. The mixed powder was added to a 20% PMMA-xylene solution. After the mixer is fully stirred, add 0.5% stabilizer, 0.5% dispersant, 1% antioxidant, etc., in order and continue to stir for 0.5˜6 h. Scrape the mixed metal paste onto the upper cover of a specific cooling element, and then put it in an oven at 90˜110° C. for 20˜120 min. After drying the solvent, put it into the sintering furnace. Pour N2/H2, and sinter at 700˜850° C. for 20˜120 min, and finally obtain the upper cover with capillary structure element. The upper cover and the lower cover are pasted with solder paste, and finally the finished cooling element is obtained, and the temperature difference between the cold end and the hot end is tested.

Embodiment 8: Take the electrolytic copper powder with an average particle size of 1 μm, and ammonium chloride particles with a particle size of 70˜100 μm obtained by ball milling or crushing and sieving, then mix together according to the weight ratio of 5:2 to obtain the mixed powder. The mixed powder accounts for 60% of the weight of the copper metal paste. The mixed powder was added to a 20% PMMA-xylene solution. After the mixer is fully stirred, add 0.5% stabilizer, 0.5% dispersant, 1% antioxidant, etc., in order and continue to stir for 0.5˜6 h. Paint the mixed metal paste into the upper cover of the specific cooling element, then put it into an oven at 90˜110° C. for 20˜120 min, after drying the solvent, put it into the sintering furnace, pass N2/H2, and sinter at 700˜850° C. for 20˜120 min, finally, the upper cover with capillary structure element is obtained. The upper cover and the lower cover are pasted with solder paste, and finally the finished cooling element is obtained, and the temperature difference between the cold end and the hot end is tested.

Embodiment 9: Take the electrolytic copper powder with an average particle size of 1 μm, and ammonium chloride particles with a particle size of 70˜100 μm obtained by ball milling or crushing and sieving, then mix together according to the weight ratio of 2:1 to obtain the mixed powder. The mixed powder accounts for 70% of the weight of the copper metal paste. Add to the 20% PMMA-xylene solution and stir well in the mixer. Add 0.5% stabilizer, 0.5% dispersant, 1% antioxidant in sequence, and continue stirring for 0.5˜6 h. Paint the mixed metal paste into the upper cover of the specific cooling element, then put it into an oven at 90˜110° C. for 20˜120 min, after drying the solvent, put it into the sintering furnace, pass N2/H2, and sinter at 700˜850° C. for 20˜120 min, finally, the upper cover with capillary structure element is obtained. The upper cover and the lower cover are pasted with solder paste, and finally the finished cooling element is obtained, and the temperature difference between the cold end and the hot end is tested.

As shown in the table below, the temperature difference between the cold end and the hot end obtained by the cooling element test prepared by the embodiment 1-9. (E=Embodiment)

| Test | E1 | E2 | E3 | E4 | E5 | E6 | E7 | E8 | E9 |
|---|---|---|---|---|---|---|---|---|---|
| Average | 4.1° C. | 3.6° C. | 3.8° C. | 3.5° C. | 3.0° C. | 2.5 | 3.5° C. | 3.8° C. | 4.0° C. |
| temperature | | | | | | | | | |
| difference | | | | | | | | | |

As shown in the table above, the cooling element prepared by the preparation method provided by the present invention is arranged with good thermal conductivity.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A capillary structure element of a cooling element prepared and formed by copper metal paste; wherein the copper metal paste includes copper powder, binder, solvent, pore former, dispersant, stabilizer, surfactant, and antioxidant.

2. The capillary structure element as described in claim 1, wherein the capillary structure element is a three-dimensional interconnected hole structure with a hole diameter of 10-100 μm and a porosity of 30-80%. 3.

3. The capillary structure element as described in claim 1, wherein the microscopic shape of the copper powder is spherical, and the particle size of the copper powder is 0.1-100 μm.

4. The capillary structure element as described in claim 1, wherein the binder is in PVA, epoxy resin, acrylic resin, phenolic resin, modified phenolic resin, hydroxymethyl cellulose and ethyl cellulose one or more; the solvent is one or more of ethanol, propanol, isopropanol, acetone, toluene, xylene, terpineol, triethanolamine, isophorone, divalent ester and water; the pore former is one or more of ammonium chloride, urea, ammonium sulfate, citric acid and benzoic acid; the dispersant is one or more of methyl amyl alcohol, cellulose derivatives, polyacrylamide and fatty acid polyethylene glycol ester; the stabilizer is one or more of phosphites, epoxy compounds and polyols; escribed surfactant is sodium dodecyl sulfate, sodium dodecyl benzene sulfonate, sodium tetradecyl sulfonate, sodium hexadecyl sulfonate, lecithin, triethanolamine, KH550, polyethylene glycol and triglyceride. One or more of ethanolamines; the antioxidant is one or more of citric acid, phytic acid, vitamin, oxalic acid, ascorbic acid and glucose.

5. The capillary structure element as described in claim 1, wherein a weight ratio of described copper powder and described pore former is 3:1˜1:1.

6. The capillary structure element as described in claim 5, wherein a weight fraction ratio of the mixture of the copper powder and the pore former to the copper metal paste is 50% to 80%.

7. A cooling element comprising a lower cover, an upper cover that is covered and connected to the lower cover and forms an accommodation cavity with the lower cover, a cooling medium that is accommodated in the accommodation cavity, and a capillary structure element as described in claim 1 loaded on the upper cove, wherein the capillary structure element is accommodated in the accommodation cavity and adsorbs the cooling medium.

8. A preparation method of a cooling element, comprising steps of:
providing an upper cover and a copper metal paste as claimed in claim 1, wherein the copper metal paste is supported on the upper cover by a blade coating method or a screen printing method; the copper metal paste on the upper cover is successively subjected to drying treatment and high temperature sintering treatment to obtain the capillary structure element as described in claim 1.

9. The preparation method of cooling element as described in claim 8, wherein the drying process includes placing the upper cover loaded with the copper metal paste into an oven or a vacuum oven for drying process.

10. The preparation method of cooling element as described in claim 8, wherein the high temperature sintering treatment is carried out in an atmosphere in which nitrogen is used as a protective gas and hydrogen is used as a reducing gas.
